(19) United States
(12) Patent Application Publication
(10) Pub. No.: US 2026/0076192 A1
(43) Pub. Date: Mar. 12, 2026

(54) THERMAL INTERFACE MATERIAL FOR SEMICONDUCTORS

(71) Applicant: Taiwan Semiconductor Manufacturing Company, Ltd., Hsinchu (TW)

(72) Inventors: Yu-Sheng Lin, Zhubei (TW); Jia-Shen Lan, Taipei (TW); Jui Shen Chang, Taichung (TW); Jyun-Lin Wu, Hsinchu (TW); Yao-Chun Chuang, Hsinchu (TW)

(21) Appl. No.: 18/882,899

(22) Filed: Sep. 12, 2024

(51) Int. Cl. H01L 23/373; H01L 21/48; H01L 23/00; H01L 23/367

(52) U.S. Cl. CPC H10W 40/255; H10W 40/037; H10W 40/228; H10W 40/251; H10W 40/253; H10W 74/15; H10W 76/12; H10W 90/724; H10W 90/734

(57) ABSTRACT

A thermal interface film is used between a semiconductor die and a heat sink. The thermal interface film includes at least two layers, a first layer with vertically oriented graphite and a second layer with horizontally oriented graphite. The thermal interface film directs heat away from the semiconductor die both upwards and outwards, spreading the heat over a larger surface area more quickly.

### BACKGROUND

Various computer applications require the use of a large number of computer processors. Examples of such applications may include high performance computing (HPC), cloud computing, data centers, and artificial intelligence. Heat dissipation during operation of the computer processors is desirable.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of one embodiment of a processor module, in accordance with some embodiments of the present disclosure. The module includes a semiconductor package and a heat sink. A thermal interface film is used to transfer heat from the semiconductor package to the heat sink more efficiently.

FIG. 2A is a cross-sectional view of the thermal interface film, in accordance with some embodiments of the present disclosure. This embodiment has three layers, with the horizontally oriented graphite layer being located between the other two layers.

FIG. 2B is a first plan view showing the thermal interface film relative to the semiconductor die and two memory chips.

FIG. 2C is a second plan view showing the thermal interface film relative to the semiconductor die and additional memory chips.

FIG. 3A is a cross-sectional view showing a layer with vertically oriented graphite. FIG. 3B is a cross-sectional view showing a layer with horizontally oriented graphite.

FIG. 4A is a cross-sectional view of another embodiment of the thermal interface film. In this three-layer embodiment, the first layer with vertically oriented graphite is thicker than the third layer with vertically oriented graphite.

FIG. 4B is a cross-sectional view of another embodiment of the thermal interface film. In this three-layer embodiment, the third layer with vertically oriented graphite is thicker than the first layer with vertically oriented graphite.

FIG. 5A is a cross-sectional view of another embodiment of the thermal interface film. In this embodiment, horizontally oriented graphite is only present in the part of the layer above the semiconductor die. FIG. 5B is a plan view showing the thermal interface film relative to the semiconductor die and two memory chips.

FIG. 6A is a cross-sectional view of another embodiment of the thermal interface film. In this embodiment, horizontally oriented graphite is present within a peripheral region of the layer above one or more edge regions of the semiconductor die. FIG. 6B is a plan view showing the thermal interface film relative to the semiconductor die and two memory chips.

FIG. 7A is a cross-sectional view of another embodiment of the thermal interface film, in accordance with some embodiments of the present disclosure. This embodiment has two layers, with the horizontally oriented graphite layer being located below the vertically oriented graphite layer.

FIG. 7B is a cross-sectional view of another embodiment of the thermal interface film having two layers, where the horizontally oriented graphite layer is located above the vertically oriented graphite layer.

FIG. 8A is a cross-sectional view of another embodiment of the thermal interface film. In this embodiment, the film is a single layer that comprises both vertically oriented graphite and horizontally oriented graphite.

FIG. 8B is a plan view showing the thermal interface film relative to the semiconductor die and two memory chips.

FIG. 9 is a cross-sectional view of another embodiment of a processor module, in accordance with some embodiments of the present disclosure. In this embodiment, the thermal interface film directly contacts both the semiconductor die and the heat sink.

FIG. 10 is a cross-sectional view of another embodiment of a processor module, in accordance with some embodiments of the present disclosure. In this embodiment, the semiconductor package includes a semiconductor die and a lid. A first thermal interface film is located between the semiconductor die and the lid. A second thermal interface film is located between the lid and the heat sink.

FIG. 11 is a flow chart illustrating a method for making a thermal interface film, in accordance with some embodiments.

FIG. 12 is a flow chart illustrating a method for making a processor module, in accordance with some embodiments.

FIG. 13 is a schematic illustration of a set of servers in a data center, and connections to a real-time monitoring system for monitoring the health of the processor modules in the data center.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” or “over” are used with reference to two different layers (including the substrate), they indicate merely that one layer is on, upon, or over the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The term “semiconductor die”, as used in the present disclosure, refers to a substrate having one or more integrated circuits, also commonly referred to as a chip or microchip.

The term “semiconductor package”, as used in the present disclosure, refers to the combination of one or more semiconductor dies and one or more interconnect layers that permit the integrated circuit(s) to communicate with one or more other packages. Examples of an interconnect layer may include a redistribution layer (RDL) or an interposer having bond pads or C4 bumps or pillars.

The present disclosure relates to processor modules with improved thermal transfer efficiency to increase heat disspation. Semiconductor dies can be packaged in many different ways, such as Package-on-Package (PoP) where two semiconductor packages are stacked upon each other, or Chip-on-Wafer-on-Substrate (CoWoS) where a semiconductor die is attached to a wafer (e.g. interposer) which is then attached to a substrate (e.g. printed circuit board). These may also be referred to as three-dimensional integrated circuit (3DIC) devices.

Heat dissipation during operation is still a problem. Prolonged exposure to excessive temperatures may decrease the reliability and operating lifetime of the semiconductor die. To address this problem, a thermal interface material (TIM) is applied over the semiconductor die to improve thermal coupling to a heat sink. The heat sink may be secured in place relative to the die using a fastener system, for example by using a clamp or screws. In some TIM processes, the die is exposed in the package, and the TIM is applied between the die and the heat sink. In other TIM processes, the package includes a lid (which can act as a heat spreader to spread the thermal energy over a larger surface area) and the TIM is applied between the lid and the heat sink. However, the TIM and the lid generally do not efficiently spread the heat, which is disproportionately generated by the semiconductor die (compared to other components such as memory). For example, the thermal conductivity of SUS304, a common stainless steel alloy used for the lid, is only ˜14-17 W/m·K. As a result, the thermal energy remains above the semiconductor die, which reduces its lifespan. In the present disclosure, a thermal interface film is used, which acts as a good heat spreader to more uniformly spread and dissipate thermal energy, extending the lifespan of the semiconductor die.

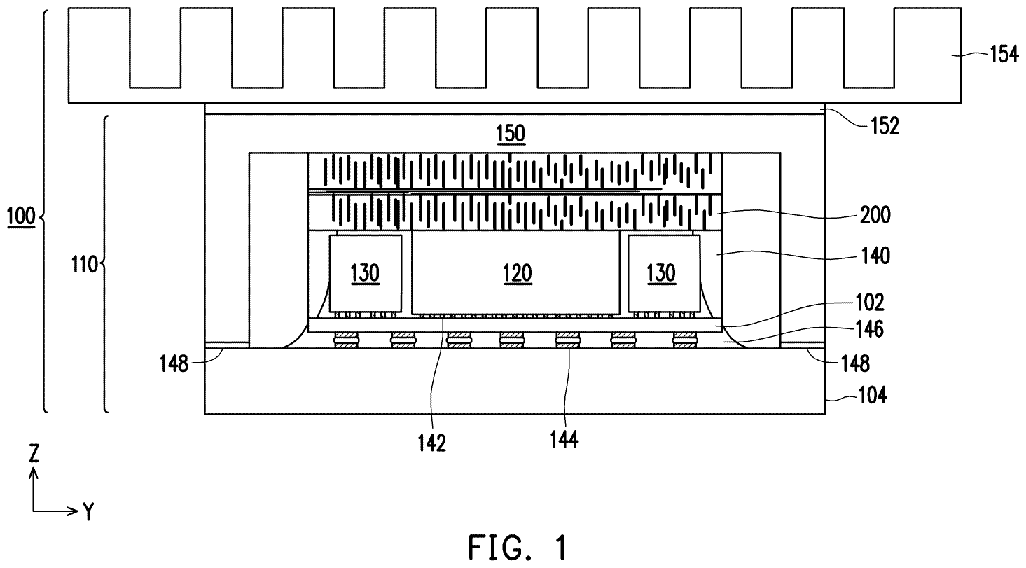

FIG. 1 is a cross-sectional view of one embodiment of a processor module 100 of the present disclosure. Initially, a semiconductor package 110 is shown. Here, the package includes a semiconductor die 120 in the form of a system-on-a-chip (SoC). On an SoC, many electronic components are combined together on one common substrate. The SoC contains a semiconductor die, and is shown here as being located between two memory chips 130. The SoC 120 generates a relatively large amount of heat compared to the memory chips 130. The SoC may contain, for example, a central processing unit (CPU) or a graphics processing unit (GPU). The memory chips may be, for example, high bandwidth memory (HBM). Other electronic components may also be present. Generally, any number of dies/chips may be present in the package 110 and the processor module 100. The SoC 120 may be surrounded on its sides by molding or encapsulant 140.

The SoC 120 is bonded to the top surface of a wafer 102. This may be done, for example, through a first interconnect layer 142 containing electrical contacts such as lands, balls, pins, bumps, pillars, or other similar structures. The wafer 102 may be an interposer substrate, formed from a semiconductor substrate like silicon. Sometimes, active devices (like transistors) and passive devices (such as resistors or capacitors) are formed on the surface of the wafer. The wafer may also include through-vias.

The wafer 102 is then bonded to the top surface of a substrate 104 to obtain the semiconductor package 110, which is shown here as a Chip-on-Wafer-on-Substrate (CoWoS). Again, this may be done through a second interconnect layer 144 containing electrical contacts such as lands, balls, pins, bumps, pillars, or other similar structures. The substrate 104 may be, for example, a printed circuit board (PCB), or the like. The substrate 104 may again include other active or passive devices. An underfill material 146 is shown here between the SoC 120 and the wafer 102, and also between the wafer 102 and the substrate 104. The backside of the substrate may also include an interconnect layer (not shown) which will be used to join the semiconductor package to the motherboard.

Continuing, a thermal interface film 200 is placed over the semiconductor package 110 to improve thermal coupling. The film may be referred to herein as a first or inner TIM layer. In some embodiments, the thickness of the first TIM layer may range from 50 micrometers (μm) to about 3 millimeters (mm), although other ranges are within the scope of the present disclosure. The thermal interface film will be discussed in more detail further herein.

An adhesive 148 is also disposed upon the substrate 104 and around the SoC 120. The adhesive 148 may be, for example, an epoxy, or a silicon resin, a glue, or other adhesive suitable for use with semiconductor devices.

A lid 150 is attached to the substrate 104 and over the semiconductor die 120. The lid both physically protects the die 120, and also acts as a heat spreader that dissipates heat generated by the SoC over the greater surface area of the lid. The lid is usually made from a material with high thermal conductivity, such as aluminum, steel, stainless steel, copper, and other similar materials. The lid 150 is affixed to the wafer by the adhesive 148. The adhesive may need to be cured by applying heat at a suitable temperature for a suitable time period. The lid may also be considered part of the semiconductor package 110.

A second TIM layer 152 is placed upon the lid 150, which thermally couples the lid 150 to the heat sink 154. Suitable TIMs may include polymers, which may contain thermally conductive fillers therein. Some non-limiting examples of thermally conductive fillers may include aluminum oxide, boron nitride, aluminum nitride, aluminum, copper, silver, and indium. The TIM may be a film or a sheet, including for example carbon nanotubes (CNTs) or graphite. The TIM may be in the form of a solid pad, paste, gel, grease, or a phase change material, among others. The TIM may be applied continuously over the lid.

The heat sink 154 is placed above the second TIM layer. The heat sink may be made of materials such as aluminum or copper. The heat sink may include fins to increase surface area. The heat sink may be held in place against the semiconductor package by suitable means, for example a clamp or screws.

The combination of the semiconductor package 110 and the heat sink 154 is referred to herein as a processor module 100. It is noted that the present disclosure also extends to bare die packages that do not include a lid and thus only have one TIM layer instead of two TIM layers, and such combinations are also considered processor modules within the scope of the present disclosure.

Although not illustrated, each processor module can also include internal cache, memory, input/output controllers, buses for passing data, and other similar components. Communication channels can include a system bus, network connection, wired, and wireless systems. Each processor module can include one or more cores. Each processor module performs instructions based on software / programming as desired.

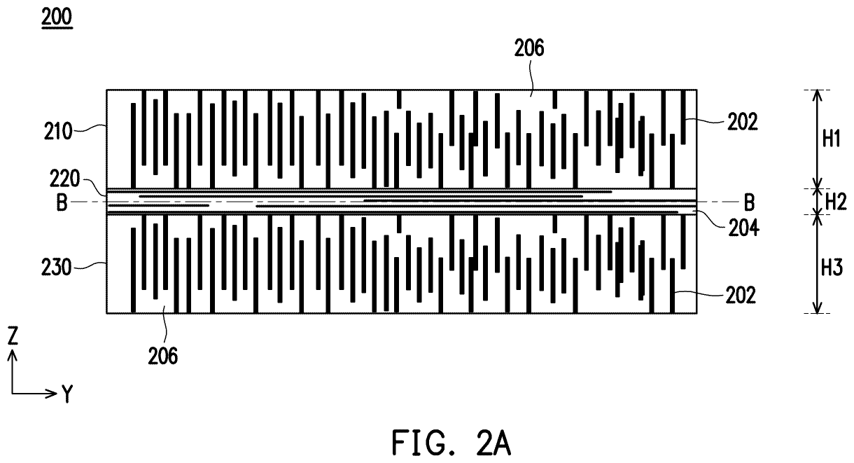

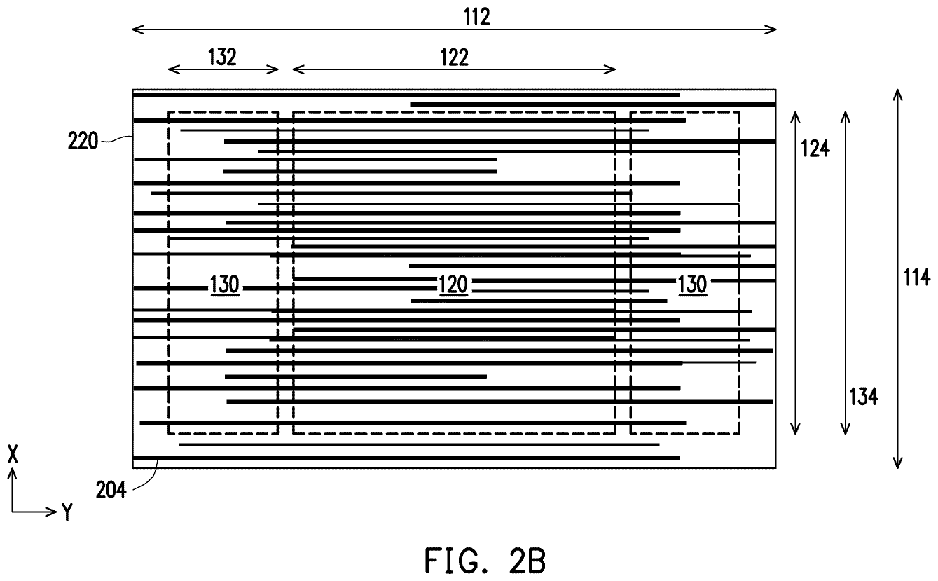

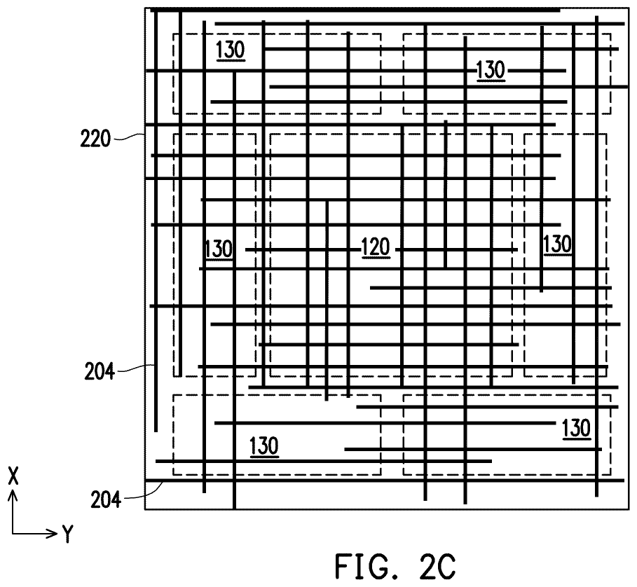

Referring now to FIG. 2A, a side cross-sectional view illustrates this embodiment of the thermal interface film 200, which is a sandwich structure made of three layers, a first layer 210, a second layer 220, and a third layer 230. The second layer 220 is located between the first layer 210 and the third layer 230, and directly contacts each layer 210, 230. Each layer includes graphite.

In the first layer 210 and the third layer 230, the graphite is vertically oriented, as indicated with reference numeral 202. Horizontally oriented graphite is present in either of these two layers in only very small amounts relative to the vertically oriented graphite (at most 5 wt % of the graphite in the layer). In the second layer 220, the graphite is horizontally oriented, as indicated with reference numeral 204. Vertically oriented graphite is present in the second layer in only very small amounts relative to the horizontally oriented graphite (at most 5 wt % of the graphite in the layer). More generally, the graphite 202 in the first layer 210 and the third layer 230 is oriented in a first plane or volume, and the graphite 204 in the second layer 220 is oriented in a second plane or volume which is different from the first plane or volume.

In this regard, graphite has high thermal conductivity in the in-plane direction, but poor thermal conductivity in the out-plane direction. The thermal conductivity of graphite in the in-plane direction begins at ˜400 W/m·K and goes even higher. The phrase “vertically oriented” indicates the direction of high thermal conductivity is away from the semiconductor die in the direction of the Z-axis, towards the heat sink 154. In other words, the in-plane direction of the graphite is directed away from the semiconductor die towards the heat sink, or out of the plane of the thermal interface film itself. The phrase “horizontally oriented” indicates the direction of high thermal conductivity is in the direction away from the semiconductor die towards the sides of the package, as indicated by the Y-axis (and the X-axis). The in-plane direction of the graphite is in the plane of the thermal interface film. As a result, the vertically oriented graphite layer(s) quickly transfer heat away from the semiconductor die to the lid and the heat sink, while the horizontally oriented graphite layer quickly spreads the heat away from the semiconductor die across a larger surface area (for example, the surface area over the memory chips, which have a significantly lower operating temperature).

The graphite within the layers of the thermal interface film is usually in the form of flakes or small sheets and have a height of at least 100 nanometers, and have different properties than a stack of graphene. It is noted that the individual pieces of graphite are considered together as a whole. For example, it is not required that each piece of graphite must extend entirely across the entire length/width/height of a given layer. This is illustrated here with individual lines which are short or long. In the aggregate, heat can be transferred more quickly along the in-plane direction of the graphite.

Continuing, each layer of the thermal interface film may individually also comprise a binder resin or polymeric resin 206, in which the graphite is dispersed. Suitable polymeric resins generally have a high melting point to accommodate the high operating temperatures of the semiconductor die. Some non-limiting examples of suitable polymeric resins may include silicones, polyetherimides (PEI), polyetheretherketones (PEEK), polytetrafluoroethylene (PTFE), polybenzimidazoles (PBI), polyimides (PI), polyphenylene sulfides (PPS), polyethersulfones (PES), some polyethylenes such as HDPE, polypropylenes, polyethylene terephthalates (PET), polybutylene terephthalates (PBT), and epoxies. However, the presence of a polymeric resin is not required. For example, pyrolytic graphite sheets can be used for the layers containing vertically oriented graphite.

Continuing with FIG. 2A, the first layer 210 has a first height H1. The second layer 220 has a second height H2. The third layer 230 has a third height H3. In particular embodiments, the second height H2 is less than the first height H1. In other particular embodiments, the second height H2 is less than the third height H3. Put another way, the ratios H2/H1 and H2/H3 are between zero and one. As illustrated here, H1 and H3 are about equal to each other.

In some embodiments, H1 and H3 may independently range from about 40 micrometers (μm) to about 200 micrometers. In some embodiments, H2 may vary from about 5 micrometers (μm) to about 100 micrometers. Combinations of these heights are contemplated, and other ranges and values are also within the scope of this application.

FIG. 2B is a plan view through line B-B of FIG. 2A. The length 112 and width 114 of the semiconductor package 110 are indicated. The semiconductor die 120 and the two memory chips 130 are also illustrated. The semiconductor die 120 has length 122 and width 124. Similarly, each memory chip 130 has a length 132 and width 134. The semiconductor package may be considered to have a length which is greater than its width.

In particular embodiments, the semiconductor die has a length 122 of from about 20 millimeters (mm) to about 70 mm. In particular embodiments, the semiconductor die has a width 124 of from about 5 millimeters (mm) to about 50 mm. Combinations of these values are contemplated, and other ranges and values are also within the scope of this application.

In particular embodiments, the memory chips each have a length 132 of from about 5 millimeters (mm) to about 30 mm. In particular embodiments, the memory chips each have a width 134 of from about 5 millimeters (mm) to about 30 mm. Combinations of these values are contemplated, and other ranges and values are also within the scope of this application. It is noted that the length 112 and width 114 of the semiconductor package are greater than the individual lengths and widths of the semiconductor die or memory chip.

Continuing with FIG. 2B, the horizontally oriented graphite 204 is illustrated here as being oriented only in the direction of the Y-axis. Generally, it is desirable for the graphite to overlap both high-heat areas and low-heat areas (heat being measured relative to each other). For example, here, the graphite overlaps the high-heat semiconductor die 120 and the two low-heat memory chips 130. The second layer 220 of the thermal interface film is shown here as having dimensions about equal to that of the semiconductor package.

However, the plan view of FIG. 2C illustrates an embodiment where the horizontally oriented graphite 204 is illustrated as being oriented in both directions along the Y-axis and the X-axis. Such an embodiment may be useful, for example, when there is additional surface area in the semiconductor package along both the Y-axis and the X-axis. For example, in this illustration, additional memory chips 130 are present around the semiconductor die 120.

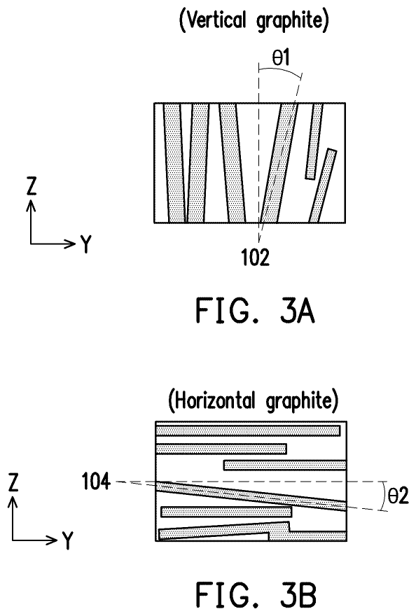

Referring now to FIG. 3A, the plane of the graphite may have an angle Θ1 which is measured relative to a vertical axis 102. The graphite may be considered to be vertically oriented if the angle Θ1 is between 0° and 15°. Similarly, referring to FIG. 3B, the plane of the graphite may have an angle Θ2 which is measured relative to a horizontal axis 104. The graphite may be considered to be horizontally oriented if the angle Θ2 is between 0° and 30°. More generally, the angle formed between the first plane or volume and the second plane or volume is at least 45°.

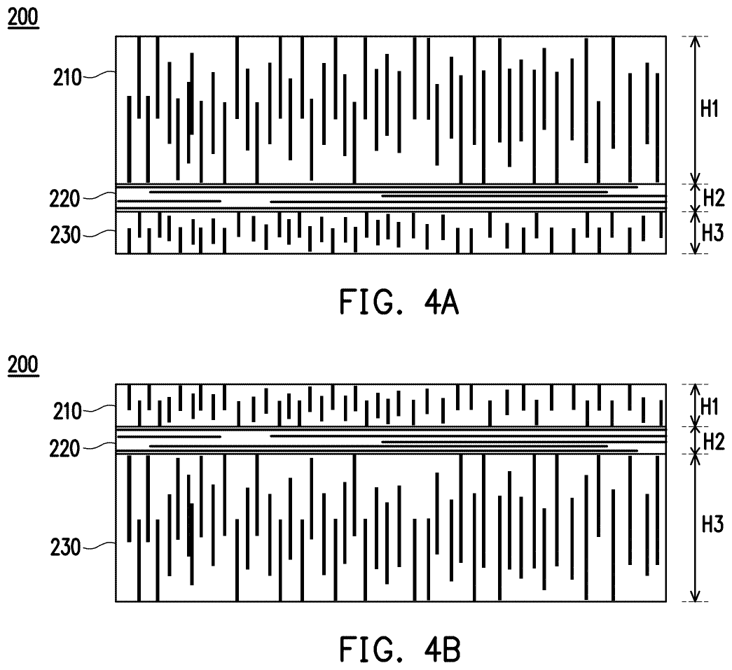

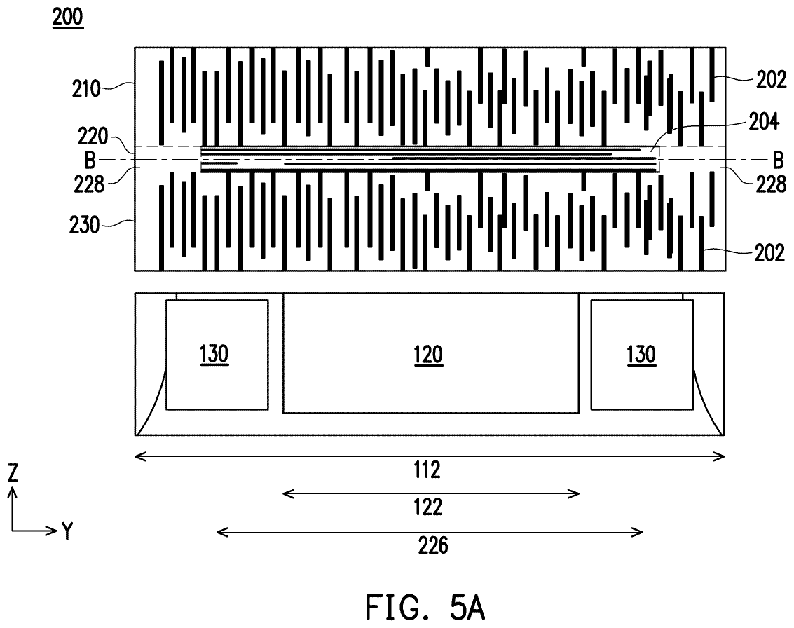

FIG. 4A and FIG. 4B illustrate two additional embodiments of a three-layer thermal interface film 200 with layers 210, 220, 230 as previously described. Referring first to FIG. 4A, as illustrated here, H1 is greater than H3. This may be useful if the surface of the lid has a high surface roughness. Referring next to FIG. 4B, as illustrated here, H3 is greater than H1. This may be useful if the surface(s) of the semiconductor die and/or the memory chips have a high surface roughness.

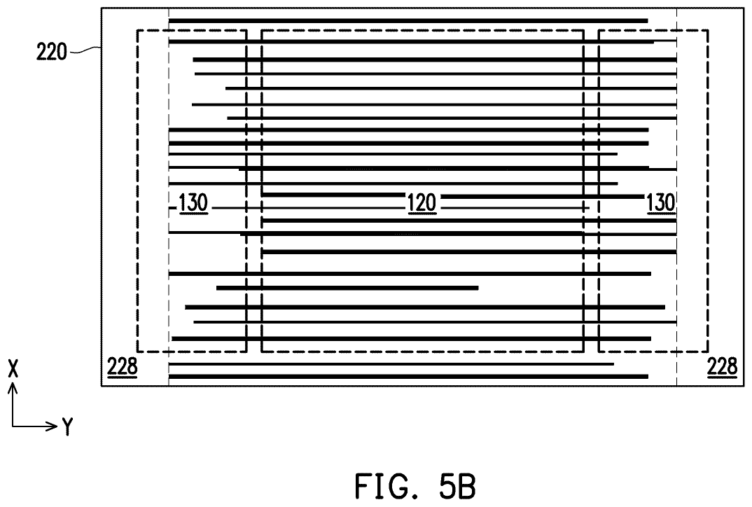

FIG. 5A and FIG. 5B illustrate one further embodiment of the thermal interface film. In this embodiment, the horizontally oriented graphite 204 in the second layer 220 is not dispersed throughout the entire layer, but rather is present in specified parts of the layer. In FIG. 5A, the semiconductor die 120 has a length 122, and the semiconductor package 110 has a length 112. The horizontally oriented graphite is located within a length 226 that is greater than the length 122 of the semiconductor die, but less than the length 112 of the semiconductor package. Two empty regions 228 are indicated. In particular embodiments, the amount of graphite (by mass) in the empty regions is at least 10 times less than the amount of graphite in the other part in the layer. FIG. 5B is a plan view through line B-B of FIG. 5A. As better seen here, this embodiment still permits heat to be spread away from the entirety of the semiconductor die 120 to the surface area above the memory chips 130.

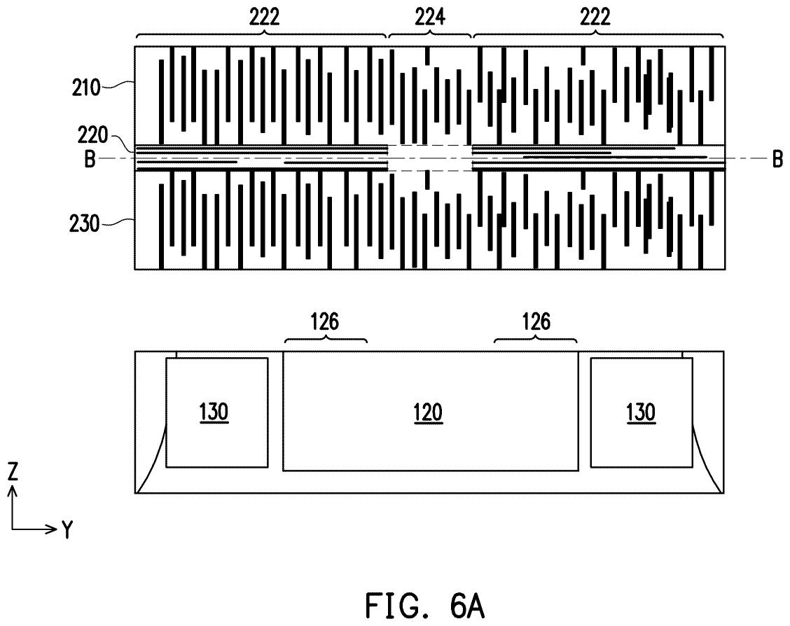

In the embodiment illustrated in FIG. 6A and FIG. 6B again, the horizontally oriented graphite in the second layer 220 is not dispersed throughout the entire layer. Again, FIG. 6B is a plan view through line B-B of FIG. 6A. As illustrated here, the semiconductor die 120 may be considered to have at least one edge region 126. Here, two such edge regions 126 are shown. The second layer 220 has one or more peripheral regions 222 and a central region 224. The horizontally oriented graphite 204 is present in the peripheral region(s) 222, and is not present in the central region 224, i.e. the central region is an empty region. In the cross-sectional view, the peripheral region(s) 222 of the second layer overlap the edge region(s) 126 of the semiconductor die. In particular embodiments, the edge region(s) 126 are from about 1% to about 99%, or from about 1% to about 90%, or from about 1% to about 80% of the surface area of the semiconductor die. Put another way, the area not covered by the horizontally oriented graphite is usually relatively small. In this embodiment, heat generated within the edge region(s) of the semiconductor die is spread away to the surface area above the memory chips. Heat generated near the center of the semiconductor die then spreads passively to the edge region(s) of the semiconductor die. It is noted that although FIGS. 5A-6B describe and illustrate the only second layer having empty regions, the first layer and the third layer may also have similar empty regions if desired. These embodiments permit less graphite to be used while still attaining acceptable heat spreading.

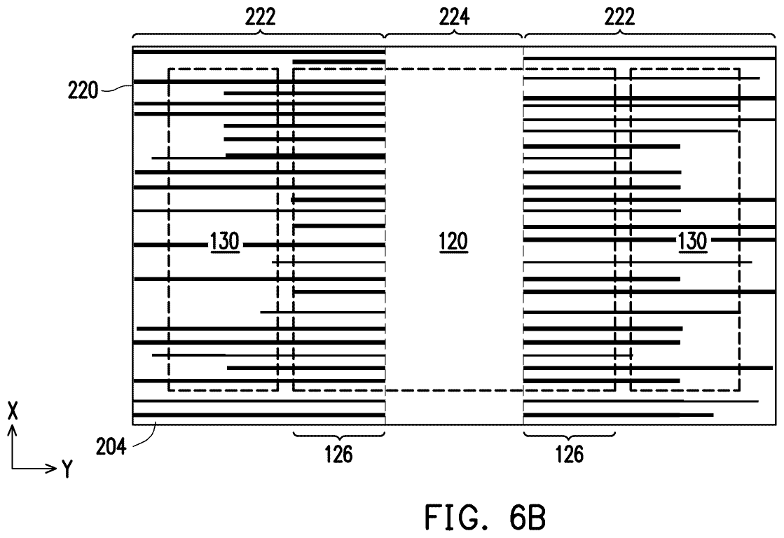

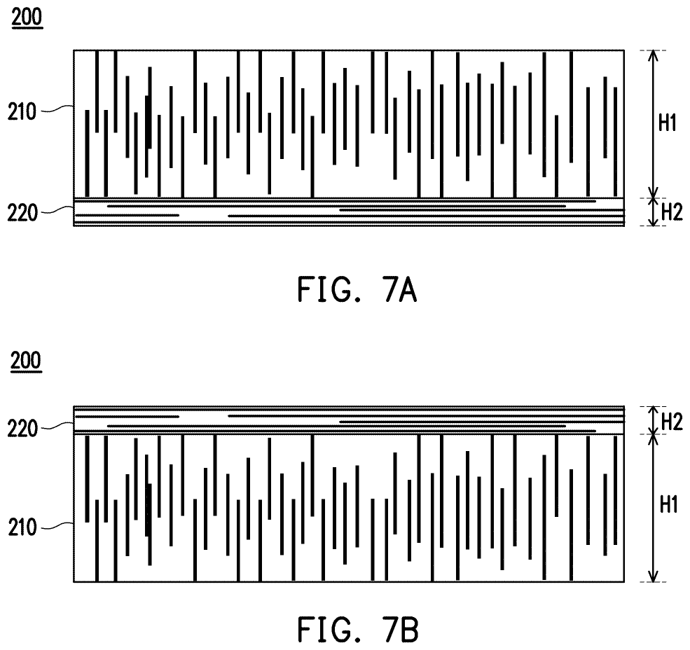

Generally, the thermal interface film 200 comprises at least the first layer 210 comprising vertically oriented graphite and the second layer 220 comprising horizontally oriented graphite. FIG. 7A and FIG. 7B illustrate two embodiments of a two-layer thermal interface film. Referring first to FIG. 7A, as illustrated here, the first layer 210 is located above the second layer 220. The second layer 220 would contact the semiconductor die. Again, this embodiment might be more useful if the lid and/or the heat sink have a high surface roughness. Referring now to FIG. 7B, here, the first layer 210 is located below the second layer 220. The first layer 210 would contact the semiconductor die. This embodiment might be useful if the surface(s) of the semiconductor die and/or the memory chips have a high surface roughness.

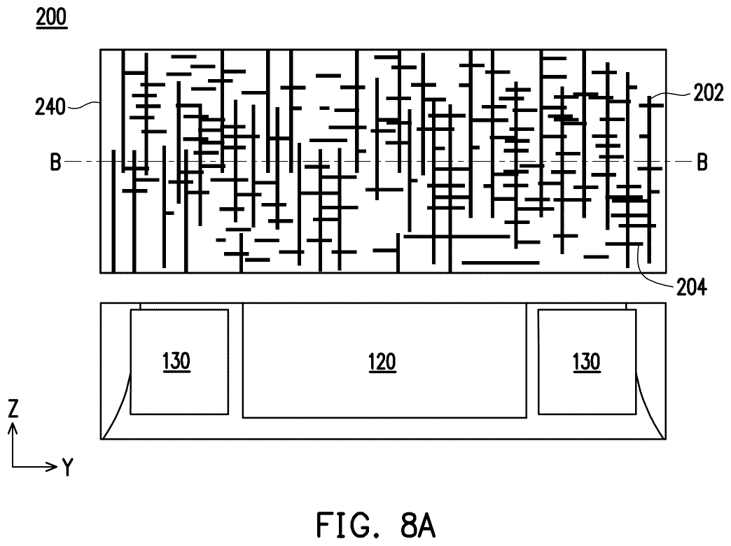

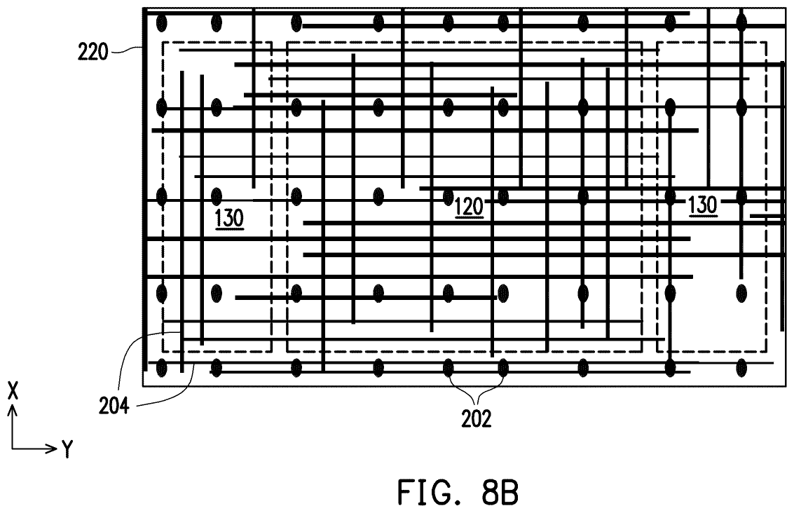

Referring new to FIG. 8A and FIG. 8B, in this embodiment, the thermal interface film 200 is a single layer 240 that includes both vertically oriented graphite 202 and horizontally oriented graphite 204. FIG. 8B is a plan view through line B-B of FIG. 8A. Here, the vertically oriented graphite 202 is represented with circles and the horizontally oriented graphite 204 is represented with lines extending both the Y-axis and the X-axis.

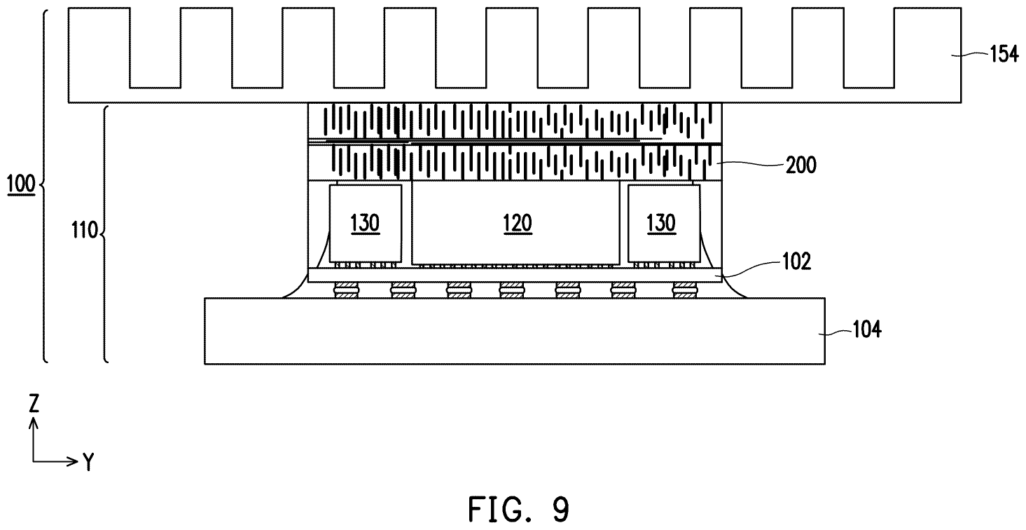

FIG. 9 is a cross-sectional view of another embodiment of a processor module 100 of the present disclosure. This embodiment includes a semiconductor die 120 and memory chips 130, a wafer 102, and a substrate 104 to obtain the semiconductor package 110. In this embodiment, no lid is present (also known as a bare die). Instead, the thermal interface film 200 directly contacts both the semiconductor die 120 and the heat sink 154.

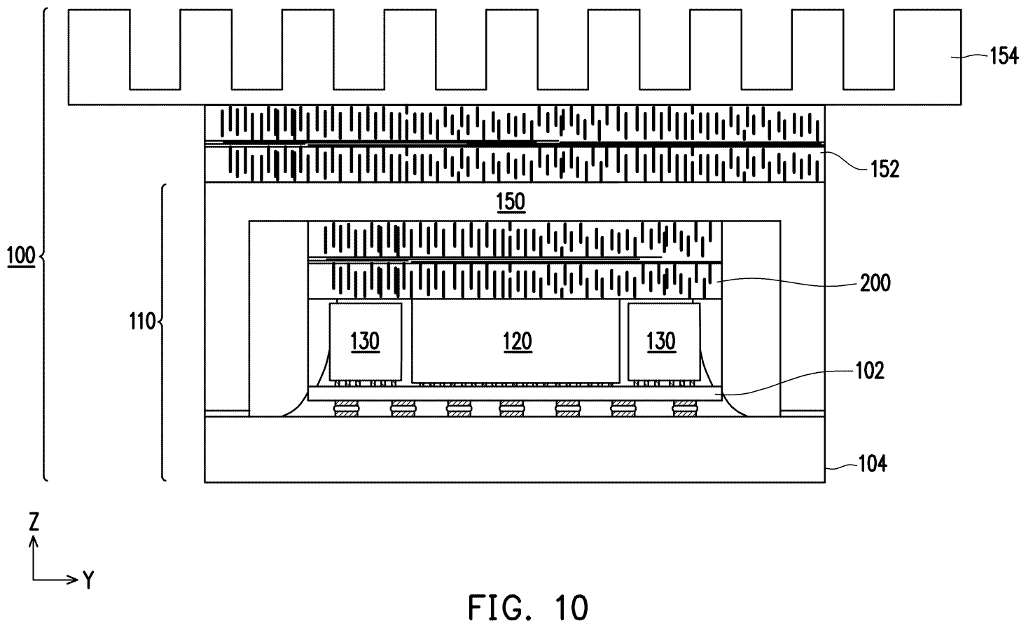

FIG. 10 is a cross-sectional view of another embodiment of a processor module 100 of the present disclosure. This embodiment is similar to that of FIG. 1. In this embodiment, the second TIM layer 152 is also a thermal interface film as described above.

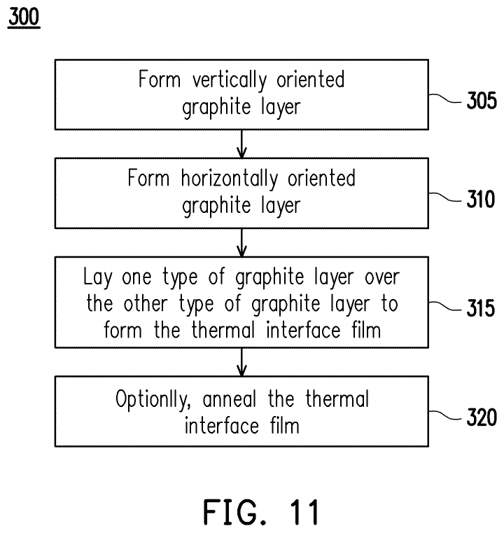

FIG. 11 is a flow chart illustrating a method 300 for making a thermal interface film, in accordance with some embodiments, and will be explained with reference to FIG. 2A. In step 305, a vertically oriented graphite layer is formed, which can be used as layers 210, 230 in the film of FIG. 2A. In step 310 of FIG. 11, a horizontally oriented graphite layer is formed, which can be used as layer 220 in the film of FIG. 2A. These two steps may be performed using conventional methods. For example, graphite can be dispersed into a polymeric solution or melt. The graphite-impregnated polymeric solution or melt may then be extruded, and the graphite can be oriented as desired by the application of magnetic fields or other orienting means. In step 315 of FIG. 11, at least one vertically oriented graphite layer and at least one horizontally oriented graphite layer are then laid upon each other to form a thermal interface film 200. Pressure may be applied to cause the layer(s) to become joined to each other, due to electrostatic forces and/or material properties. In optional step 320, the composite film can be cured to cause the layers to remain joined together.

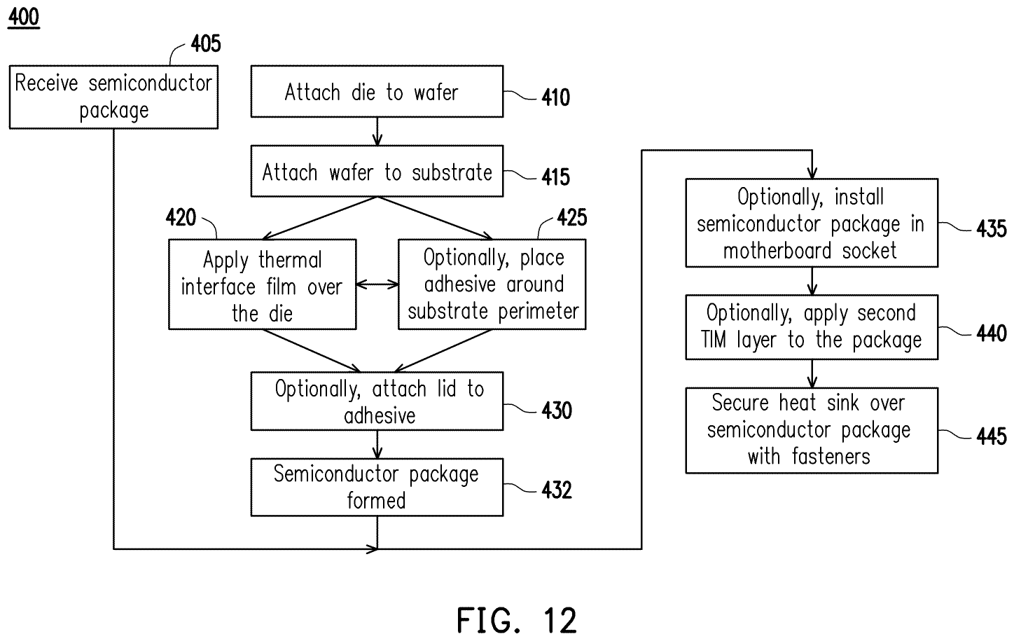

FIG. 12 is a flow chart illustrating a method 400 for applying a heat sink to a semiconductor package, in accordance with some embodiments. The method steps are discussed below in terms of forming a single processor module.

Initially, in step 405 of FIG. 12, a semiconductor package 110 is received. The semiconductor package here includes the semiconductor die 120, wafer 102, and substrate 104. Again, a lid 150 is present, but is not required.

Alternatively, a semiconductor package may be formed. In step 410, the semiconductor die 120 is attached to a wafer 102. In step 415, the wafer 102 is attached to a substrate 104. These steps would result in a bare die package.

In step 420, the thermal interface film 200 is applied to the die. The thermal interface film 200 may remain in place relative to the die due to electrostatic forces and/or material properties. If a lid is desired, then in optional step 425, an adhesive 148 is placed around a perimeter of the substrate. The order in which the thermal interface film and the adhesive are applied may be reversed. Then, in optional step 430, a lid 150 is attached to the substrate using the adhesive. The lid also contacts the thermal interface film 200. This results in a semiconductor package 110 as illustrated in FIG. 1, which is indicated as step 432. It is noted that the thermal interface film usually has a higher thermal conductivity than the lid of the semiconductor package, which helps to spread the heat more quickly.

Continuing, then, in optional step 435 of FIG. 12, the semiconductor package 110 may be installed into a socket of a motherboard. Next, in optional step 440 of FIG. 12, a second TIM layer 152 is applied to the semiconductor package to form a second TIM layer 152. This layer may be formed upon the lid (for example in FIG. 1) or upon the semiconductor die (for example the bare die of FIG. 9). The second TIM layer may be another thermal interface film, or can be some other thermal interface material.

In step 445 of FIG. 12, the heat sink is then secured over the semiconductor package. For example, a clamp or a fastener system (such as screws) may be used to hold the heat sink against the second TIM layer.

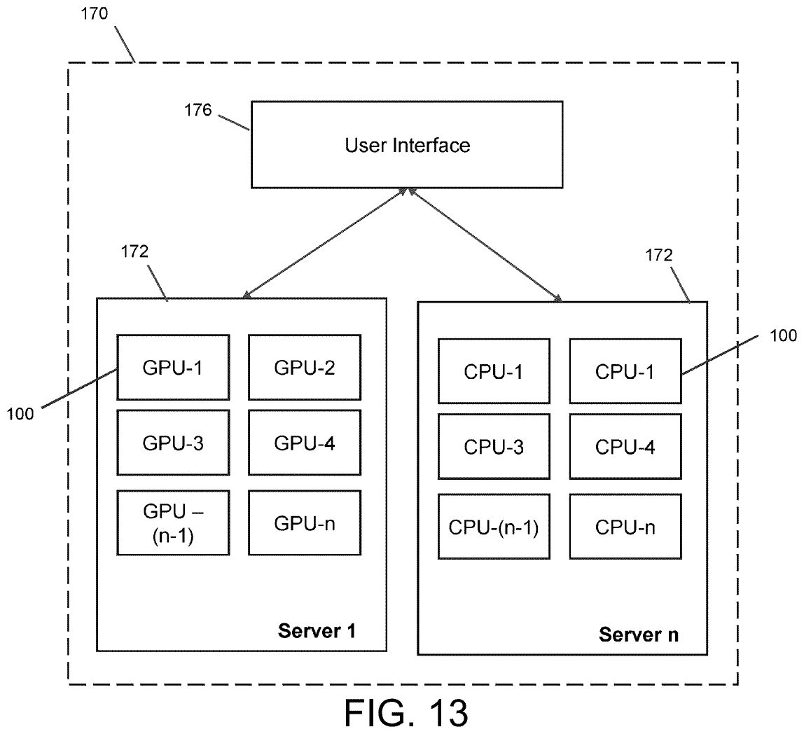

Referring now to FIG. 13, a data center 170 (represented by dashed lines) includes a set of servers 172, labeled here as Server-1 through Server-n. Each server acts as a computing node within the data center. Each server 172 contains multiple processor modules 100, which are labeled here as GPU-1 through GPU-n or CPU-1 through CPU-n for illustrative purposes. The servers and their processor modules are networked together, and are configured to send data to a user interface 176. This results in a high-performance computing (HPC) environment. The various servers can work together in parallel to process data and perform calculations more quickly.

Generally, the servers are interconnected by one or more tiers of network switches and routers. Also not illustrated here are power sources, switches, routers, hubs, gateways, firewalls, intrusion detection/prevention devices, computer terminals, printers, memory/storage devices, modems, access points, fire detection and extinguishing systems, wiring, input/output devices, fans, etc.

The processor modules of the present disclosure using the thermal interface film have several advantages. The use of the thermal interface film improves thermal transfer efficiency by spreading heat generated by the semiconductor die over a larger surface area more quickly. The heat distribution of the semiconductor package is thus more uniform. This also reduces heat accumulation over the semiconductor die, which improves its lifespan. Traditional thermal transfer materials include gel forms, which can undergo pump-out, where the thermal gel/paste is gradually moved outwards from the semiconductor die due to temperature cycle changes as the semiconductor package warps or due to uneven stresses. The reduced amount of thermal gel/paste in the desired location leads to higher temperatures and lower heat transfer efficiency. This issue is avoided with the thermal interface film.

Some embodiments of the present disclosure thus relate to methods for applying a heat sink to a semiconductor package. A thermal interface film is applied over the semiconductor package. The heat sink is then applied over the thermal interface film. It is noted that other layers may be between the thermal interface film and the heat sink, for example a lid. The thermal interface film includes at least a first layer and a second layer, the first layer comprising vertically oriented graphite and the second layer comprising horizontally oriented graphite.

Other embodiments disclosed herein relate to semiconductor packages, comprising: a semiconductor die; a thermal interface film over the semiconductor die; and a heat sink over the thermal interface film. The thermal interface film includes at least a first layer and a second layer, the first layer comprising vertically oriented graphite and the second layer comprising horizontally oriented graphite.

Also described in various embodiments herein are semiconductor packages, comprising: a semiconductor die; a thermal interface film over the semiconductor die; and a heat sink over the thermal interface film. The thermal interface film is a single layer comprising vertically oriented graphite and horizontally oriented graphite.

Some embodiments of the present disclosure also relate to methods for applying a heat sink to a semiconductor package. A thermal interface film is applied over the semiconductor package. The heat sink is then applied over the thermal interface film. It is noted that other layers may be between the thermal interface film and the heat sink, for example a lid. The thermal interface film is a single layer comprising vertically oriented graphite and horizontally oriented graphite.

Other embodiments disclosed herein relate to methods for making a thermal interface film. A vertically oriented graphite layer is formed. A horizontally oriented graphite layer is formed. At least one vertically oriented graphite layer and at least one horizontally oriented graphite layer are then laid upon each other to form a thermal interface film. Optionally, the composite film can be cured to cause the layers to remain joined together.

Other embodiments disclosed herein relate to methods for making a single-layer thermal interface film that contains both vertically oriented graphite and horizontally oriented graphite. Graphite is dispersed into a polymeric solution or melt. The graphite-impregnated polymeric solution or melt may then be extruded, and magnetic fields are applied to orient the graphite both horizontally and vertically.

Devices including a semiconductor package with a thermal interface film as described herein are also disclosed. Examples of such devices may include cellphones, cameras, computers, televisions, vehicles such as airplanes or automobiles, or other consumer electronic devices like washing machines, clothes dryers, toasters, microwave ovens, etc.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for applying a heat sink to a semiconductor package, comprising:
applying a thermal interface film over the semiconductor package; and
applying the heat sink over the thermal interface film;
wherein the thermal interface film includes at least a first layer and a second layer, the first layer comprising vertically oriented graphite and the second layer comprising horizontally oriented graphite.

2. The method of claim 1, wherein the thermal interface film further comprises a third layer that comprises vertically oriented graphite, the second layer being located between the first layer and the third layer.

3. The method of claim 2, wherein a thickness of the first layer is equal to or greater than a thickness of the third layer.

4. The method of claim 2, wherein a thickness of the first layer is less than a thickness of the third layer.

5. The method of claim 1, wherein the semiconductor package includes a semiconductor die, and either:
the horizontally oriented graphite in the second layer is located within a length that is greater than a length of the semiconductor die and less than a length of the semiconductor package or
the horizontally oriented graphite in the second layer is located within a peripheral region of the second layer that overlaps an edge region of the semiconductor die.

6. The method of claim 1, wherein the thermal interface film is applied so that the second layer is closer to the semiconductor package than the first layer.

7. The method of claim 1, wherein the thermal interface film is applied so that the first layer is closer to the semiconductor package than the second layer.

8. The method of claim 1, wherein the thermal interface film is applied to a semiconductor die of the semiconductor package, and further comprising:
applying a lid over the thermal interface film;
applying a thermal interface material to the lid; and
applying the heat sink over the thermal interface material.

9. The method of claim 1, wherein the heat sink directly contacts the thermal interface film.

10. A semiconductor package, comprising:
a semiconductor die; and
a thermal interface film over the semiconductor die;
wherein the thermal interface film includes at least a first layer and a second layer, the first layer comprising vertically oriented graphite and the second layer comprising horizontally oriented graphite.

11. The package of claim 10, wherein the thermal interface film further comprises a third layer that comprises vertically oriented graphite, the second layer being located between the first layer and the third layer.

12. The package of claim 11, wherein a thickness of the first layer is equal to or greater than a thickness of the third layer.

13. The package of claim 11, wherein a thickness of the first layer is less than a thickness of the third layer.

14. The package of claim 10, wherein the horizontally oriented graphite in the second layer is located within a length that is greater than a length of the semiconductor die and less than a length of the semiconductor package; or
wherein the horizontally oriented graphite in the second layer is located within a peripheral region of the second layer that overlaps an edge region of the semiconductor die.

15. The package of claim 10, further comprising a lid, wherein the thermal interface film is between the semiconductor die and the lid, and a thermal interface material is present between the heat sink and the lid.

16. The package of claim 10, wherein the heat sink directly contacts the thermal interface film.

17. A processor module, comprising:
a semiconductor die;
a thermal interface film over the semiconductor die; and
a heat sink over the thermal interface film;
wherein the thermal interface film is a single layer comprising graphite oriented in a first volume and graphite oriented in a second volume which is different from the first volume.

18. The processor module of claim 17, wherein an angle formed between the first volume and the second volume is at least 45°.

19. The processor module of claim 17, wherein the graphite in the first volume is vertically oriented and the graphite in the second volume is horizontally oriented.

20. The processor module of claim 17, wherein the single layer of the thermal interface film further comprises a polymeric resin.
